(19) United States
(12) Patent Application Publication
(10) Pub. No.: US 2008/0143329 A1
(43) Pub. Date: Jun. 19, 2008

(54) SEMICONDUCTOR INTEGRATED CIRCUIT FOR DETECTING MAGNETIC FIELD

(75) Inventor: Masato Ishihara, Anjo-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/947,521

(22) Filed: Nov. 29, 2007

(30) Foreign Application Priority Data
Dec. 14, 2006 (JP) 2006-337009

(51) Int. Cl. G01R 33/07; G01R 33/02

(52) U.S. Cl. 324/251; 324/252

(57) ABSTRACT

A semiconductor integrated circuit for detecting a magnetic field includes: a magneto-electric conversion element for detecting the magnetic field and converting a detected magnetic field to an electric signal, a conductive pattern for flowing a test current therethrough, the conductive pattern disposed around the magneto-electric conversion element; a detection element for detecting the electric signal of the magneto-electric conversion element when the test current flows through the conductive pattern; and an output element for outputting a test result based on the electric signal detected by the detection element

### CROSS REFERENCE TO RELATED APPLICATION

This application is based on Japanese Patent Application No. 2006-337009 filed on Dec. 14, 2006, the disclosure of which is incorporated herein by reference.

### FIELD OF THE INVENTION

The present invention relates to a semiconductor integrated circuit for detecting magnetic field.

### BACKGROUND OF THE INVENTION

A Hall element is a magneto-electric conversion element for converting a magnetic field to an electric signal by using a Hall effect. A current sensor having the Hall element is disclosed in JP-A-H07-209336. The current sensor detects magnetic field generated by current. The current sensor includes multiple magneto resistance elements, which are disposed apart from a center of a wire by different distances therebetween. The current flows in the wire.

A voltage is applied to the magneto-electric conversion element. Accordingly, when the magneto-electric conversion element short-circuits or is broken, failure of the element can be detected by measuring a signal change of the element with an external circuit. However, when characteristics of the magneto-electric conversion element deteriorate with time, or when the characteristics of an integrated circuit having the magneto-electric conversion element deviate from an allowable range, these changes can not be detected by the external circuit.

### SUMMARY OF THE INVENTION

In view of the above-described problem, it is an object of the present disclosure to provide a semiconductor integrated circuit for detecting magnetic field.

According to a first aspect of the present disclosure, a semiconductor integrated circuit for detecting a magnetic field includes: a magneto-electric conversion element for detecting the magnetic field and converting a detected magnetic field to an electric signal; a conductive pattern for flowing a test current therethrough, the conductive pattern disposed around the magneto-electric conversion element; a detection element for detecting the electric signal of the magneto-electric conversion element when the test current flows through the conductive pattern; and an output element for outputting a test result based on the electric signal detected by the detection element.

The above circuit can detect characteristic deterioration of the magneto-electric conversion element by itself.

Alternatively, the conductive pattern may be provided by a wiring layer in a multi-layered semiconductor chip. Further, the magneto-electric conversion element may be provided by a thin plate layer in the multi-layered semiconductor chip, and the conductive pattern may be disposed on a side of the magneto-electric conversion element. Furthermore, the conductive pattern may be disposed along with a periphery of the magneto-electric conversion element.

According to a second aspect of the present disclosure, a semiconductor integrated circuit for detecting a magnetic field includes: a Hall element for detecting the magnetic field and converting a detected magnetic field to an electric signal; a bus bar for flowing a constant test current therethrough, the bus bar surrounding the Hall element; and a circuit having a detection portion, an output portion and a current application circuit. The current application circuit applies the constant test current to the bus bar. The detection portion detects the electric signal of the Hall element when the constant test current flows through the bus bar. The bus bar has one of an angulated C shape, an rounded C shape, or a partially rounded U shape. The detection portion determines that the Hall element is normal when a voltage change of the electric signal before and after application of the test current is equal to or smaller than a predetermined threshold value. The detection portion determines that the Hall element is abnormal when the voltage change is larger than the predetermined threshold value. The output portion outputs a test result that the Hall element is normal or abnormal.

The above circuit can detect characteristic deterioration of the magneto-electric conversion element by itself.

### BRIEF DESCRIPTION OF THE DRAWINGS

The above and other objects, features and advantages of the present invention will become more apparent from the following detailed description made with reference to the accompanying drawings. In the drawings:

FIGS. 1A and 1B are cross sectional views showing a magneto-electric conversion element according to a first embodiment;

FIG. 2 is a circuit diagram showing the magneto-electric conversion element according to the first embodiment;

FIG. 3 is a perspective view showing the magneto-electric conversion element used with a magnet;

FIG. 4 is a flow chart showing a method for performing a self diagnosis process;

FIG. 5 is a graph showing a relationship between an output voltage and a time;

FIG. 6 is a circuit diagram showing a magneto-electric conversion element according to a second first embodiment;

FIG. 7 is a circuit diagram showing a magneto-electric conversion element according to a third first embodiment; and

FIG. 8 is a circuit diagram showing a magneto-electric conversion element according to a fourth first embodiment.

### DETAILED DESCRIPTION OF THE PREFERRED EMBODIMENTS

### First Embodiment

A semiconductor integrated circuit for detecting magnetic field according to a first embodiment of the present disclosure provides a Hall IC. The Hall IC has a function for performing self-diagnosis by applying a test magnetic field to a Hall element.

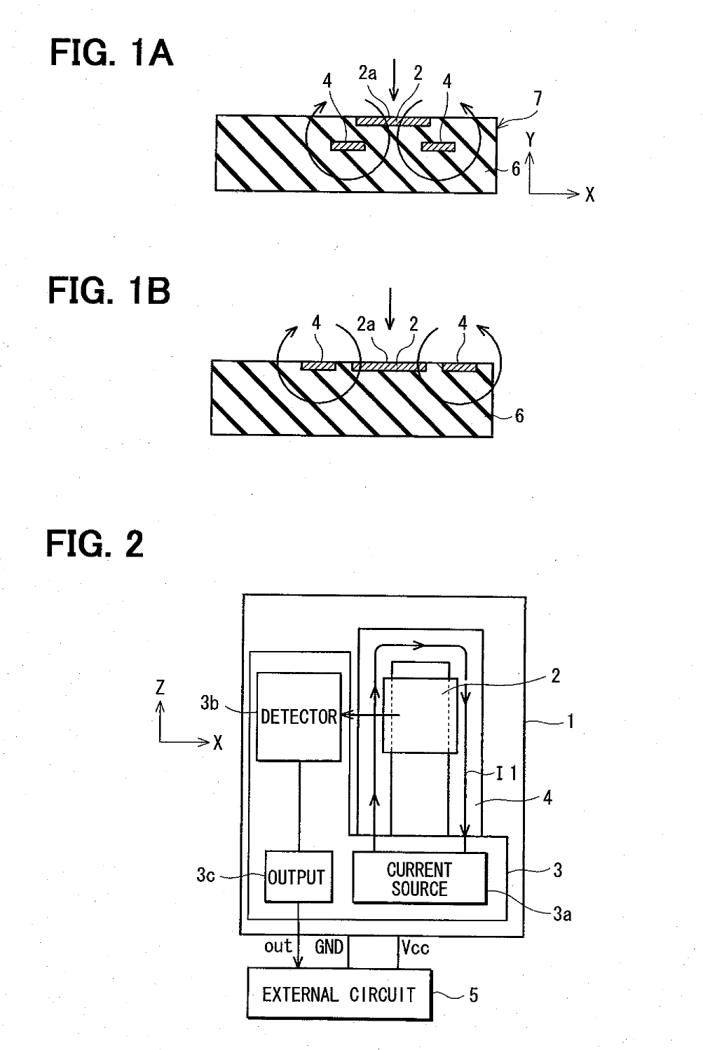

FIGS. 1A and 2B show a structure of the Hall element 2 in the Hall IC 1, and FIG. 2 shows an electric circuit diagram of the Hall IC 1. The Hall IC 1 as the semiconductor integrated circuit for detecting magnetic field includes the Hall element 2, an IC circuit portion 3 and a bus bar 4. The Hall element 2 has a square or rectangular thin plate shape. The IC circuit portion 3 is disposed around the Hall element 2. The bus bar 4 as a conductive pattern for applying a test current from the IC circuit portion 3. The Hall IC 1 is a magnetic sensor circuit, and energized with a voltage Vcc supplied from an external circuit 5.

The Hall element 2 is a magneto-electric conversion element for converting a magnetic field to a voltage as an electric signal by using a Hall effect of semiconductor. The Hall element is made of compound semiconductor such as silicon semiconductor, indium arsenide (InAs), and gallium arsenide (GaAs).

FIGS. 1A and 1B show examples of positional relationship between the Hall element 2 and the bus bar 4. The Hall element 2 is embedded in an insulation layer 6 providing the Hall IC 1. The insulation layer is disposed in a substrate 7. The bus bar 4 is spaced apart from the Hall element by a predetermined distance therebetween. A current I1 of the bus bar 4 flows along with a current path near the Hall element 2.

Specifically, a semiconductor chip for providing the Hall IC 1 has a multiple-layered structure. The Hall element 2 is embedded in one of multiple layers. The Hall element 2 has a thin plate shape. The bus bar 4 is also embedded in another one of multiple layers such that the bus bar 4 is disposed near a periphery of the Hall element 2. The bus bar 4 is formed along with the periphery of the Hall element 2. Preferably, the bus bar 4 has a rectangular shape or an angulated C shape.

The Hall element 2 and the bus bar 4 may be embedded in the same layer, as shown in FIG. 1B. Alternatively, the Hall element 2 and the bus bar 4 may be embedded in different layers, respectively, as shown in FIG. 1A.

The bus bar 4 has a long thin plate shape providing a linear pattern, and is disposed in one layer of the multiple layers of the Hall IC 1. The bus bar 4 is made of, for example, a metallic layer such as an aluminum layer and/or a semiconductor layer such as a poly crystalline silicon layer having an impurity therein. The thickness of each layer is controlled in a sub-micron order. Since the bus bar 4 is near the Hall element 2, a constant test current I1 flows in the bus bar 4 so that the strong test magnetic field is applied to the Hall element 2.

The IC circuit portion 3 includes a current application circuit 3a, a detection portion 3b, an output portion 3c and the like, so that the IC circuit portion 3 is divided into multiple electric function blocks. The current application circuit 3a is a periphery circuit having a current source, which is energized with the voltage Vcc from the external circuit 5 so that the current application circuit 3a is capable of flowing the constant current I1 as the test current through the bus bar 4. The detection portion 3b is electrically coupled with the Hall element 2, and detects a voltage as an electric signal generated in the Hall element 2. The output portion 3c outputs a test result to an external circuit based on the detection voltage of the detection portion 3b.

Since the current application circuit 3a, the detection portion 3b and the output portion 3c for testing the Hall IC 1 are mounted on the IC circuit portion 3, these circuits 3a-3c are mutually synchronized in order to test the IC 1 so that a timing for flowing the test current, a detection timing and an output timing are easily adjusted, i.e., performed in corporation with each other. Thus, without depending on the external circuit 5, the Hall IC 1 can perform a self diagnosis process by itself.

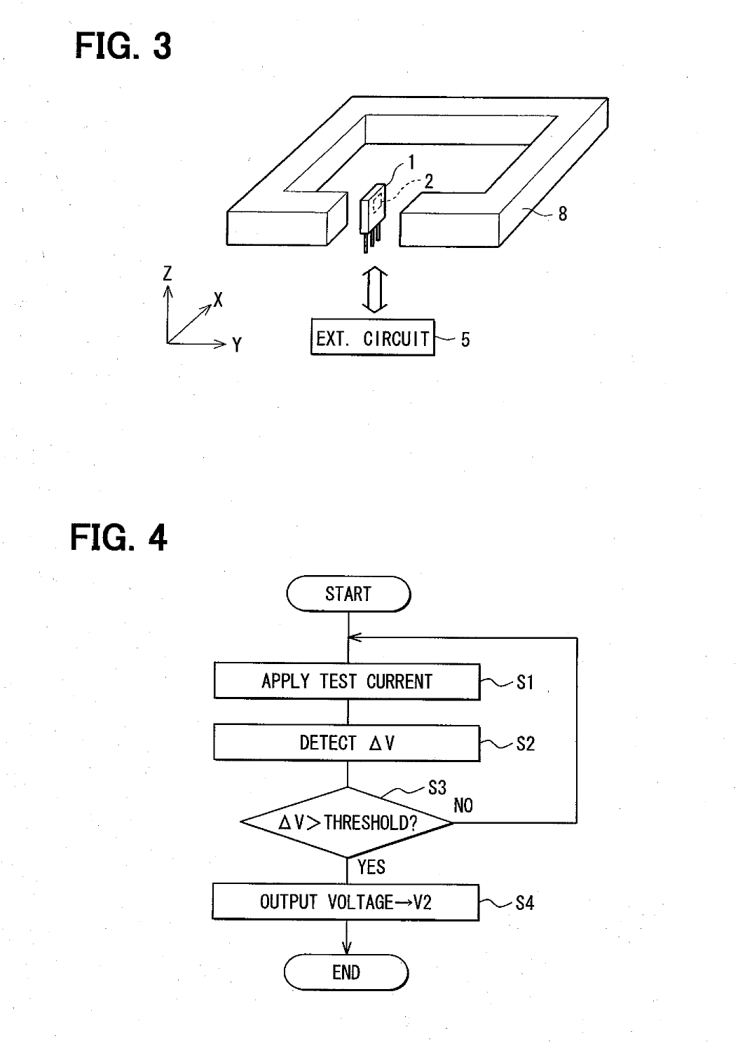

FIG. 3 shows usage of the Hall IC 1. The Hall IC 1 is provided by a SIP (system in package). When the magnetic field is applied from the magnet 8 disposed outside of the Hall IC 1, the magnetic field is detected by a magnetic field detection surface 2a. The measurement result is output to the external circuit 5 through the detection portion 3b and the output portion 3c.

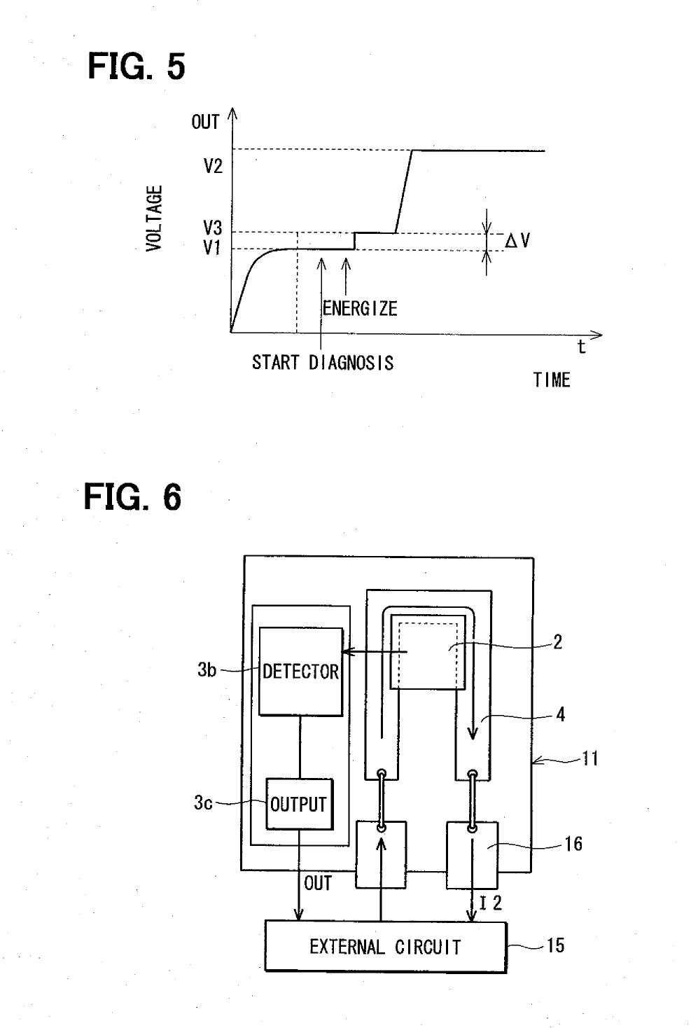

The function of the Hall IC 1 in case of a testing process is shown in FIGS. 4 and 5. The Hall IC 1 has a self diagnosis function to determine a case where the characteristics of the Hall IC 1 deviate from an allowable range and a case where the characteristics of the Hal IC 1 deteriorate with time. FIG. 4 shows a flow chart of the self diagnosis process when the Hall IC 1 self diagnoses by itself. FIG. 5 shows a change of an output voltage with time, the output voltage based on the detection result.

When the Hall IC 1 starts to self diagnose, the current application circuit 3a applies a predetermined bias current to the bus bar 4. The detection portion 3b detects the voltage generated in the Hall element 2. It is confirmed that the output voltage OUT of the output portion 3c maintains to be a predetermined reference voltage V1 during a predetermined time. Then, it is determined that an additional magnetic field applied from the outside of the Hall IC 1 is not detected. After that, the Hall IC 1 starts to self diagnose

As shown in FIG. 4, in S1, the current application circuit 3a energizes the predetermined test current I1 to the bus bar 4. A voltage change ΔV corresponding to the magnetic field is generated in the Hall element 2. The detection portion 3b detects the voltage change ΔV, and determines whether the voltage change ΔV is disposed within a predetermined range When the current application circuit 3a sets the test current I1 to be a predetermined value, and applies the current I1 to the bus bar 4, a detection voltage change of the Hall element 2 in accordance with a magnetic field change is disposed within the predetermined range if the Hall element 2 functions normally. Here, the detection voltage change corresponds to a sensitivity of the Hall element 2. Thus, when the voltage change ΔV is equal to or smaller than a predetermined threshold for criterion of determination, it is determined that the Hall element 2 functions normally (“NO” in S3). When the voltage change ΔV is larger than the threshold, it is determined that the Hall element 2 functions abnormally (“YES” in S3). In S3, when it is determined that the Hall element 2 functions abnormally, the output voltage OUT is set to be a fixed voltage V2 in S4. Further, the output voltage OUT equal to the fixed voltage V2 is output to the external circuit 5 so that the information of “abnormal Hall element” is transmitted to the external circuit 5. On the other hand, when it is determined that the Hall element 2 functions normally, the output voltage OUT is set to be a total of the voltage V1 and the voltage change ΔV. Further, the output voltage OUT equal to the total of the voltage V1 and the voltage change ΔV is output to the external circuit 5 so that the information of “normal Hall element” is transmitted to the external circuit 5.

The test current flows in the bus bar 4, so that the voltage generated in the Hall element 2 is detected by the detection portion 2b. Under the condition that the voltage change ΔV is larger than the threshold, it is determined that the Hall element 2 functions abnormally. In this case, the output voltage OUT is set to be the constant voltage V2. Thus, even when the anomaly occurs, the test result that the output portion 3c functions abnormally is output to the external circuit. Accordingly, even if the characteristics deterioration of the Hall element 2 or the like occurs, the Hall IC 1 detects the deterioration by itself. Further, this result as information of “anomaly” is transmitted to the external circuit 5.

Since the test current I1 is set to be a constant current, it is not necessary for the detection portion 3b to adjust the timing at which the test current I1 is applied. Thus, the characteristic deterioration of the Hall element 2 is easily recognized. Since the current application circuit 3a is accommodated in the Hall IC 1, the test current I1 can be applied to the bus bar 4 with synchronizing with the detection portion 3b and the output portion 3c. Thus, it is not necessary for detection to adjust the timing, and the characteristic deterioration of the Hall element 2 is easily recognized.

Since the bus bar 4 is provided by the wiring layer in the multiple layers of the Hall IC 1, the magnetic field can be applied to the Hall element 2 with a sufficiently short distance. Thus, test accuracy is improved. Since the bus bar 4 is disposed around the Hall element having the thin plate shape, the magnetic field can be applied to the Hall element 2 with much shorter distance between the Hall element 2 and the magnetic field. The magnetic field application test in a wide magnetic field range can be performed. Since the bus bar 4 is disposed along with a periphery of the Hall element 2, the distance between the magnetic field and the Hall element 2 becomes much shorter. Thus, the magnetic field application test in a wide magnetic field range can be performed. Further, the number of parts for providing the Hall IC 1 is reduced, compared with a conventional Hall IC. Thus, mounting performance to a body is improved.

Since the bus bar 4 has an angulated C shape, i.e., a short rectangular shape, the bus bar 4 is compactly accommodated in the Hall IC 1. Thus, a space in a semiconductor chip is effectively used for the Hall IC 1. Further, the number of chips obtained from one semiconductor wafer is improved.

In the conventional Hall IC defined in JP-A-H07-209336, the IC includes a conductor for flowing current therethrough and multiple magneto resistance elements so that multiple sensors are provided. The conventional Hall IC compares multiple outputs from the sensors. Accordingly, multiple circuit portions corresponding to multiple magneto resistance elements are required. However, in the present embodiment, the Hall IC 1 includes one current application circuit 3a, one detection portion 3b and one output portion 3c. Thus, the characteristic deterioration of the Hall IC 1 can be detected with reducing the dimensions of the Hall IC 1 and minimizing circuit portions in the Hall IC 1. The Hall IC 1 performs the self diagnosis by itself.

### Second Embodiment

FIG. 6 shows a Hall IC 11 according to a second embodiment of the present disclosure. Difference between the first and second embodiments is such that the test current is applied to a conductive pattern from an external circuit 15. Further, the difference is such that the test current is applied to the conductive pattern through a lead frame from the external circuit 15.

FIG. 6 explains a connection state between the Hall IC 11 and the external circuit 15. The external circuit 15 instead of the external circuit 5 shown in FIG. 2 is capable of applying the test current 12 to the Hall IC 11 instead of the Hall IC 1 shown in FIG. 2. The Hall IC 11 has a semiconductor package, to which a lead frame 16 is adhered. The current can be applied to the bus bar 4 through the lead frame 16 from the external circuit 15. Thus, the test current flows from the external circuit 15 to the bus bar 4.

When the test current flows in the bus bar 4, the magnetic field is applied to the Hall element 2. The detection portion 3b detects a voltage, i.e., an electric signal generated in the Hall element 2. The detection portion 3c outputs the test result corresponding to the detection voltage to the external circuit 15.

In the present embodiment, the test current is applied to the bus bar 4 from the external circuit 15. Thus, a large current can be applied to the Hall IC 1, compared with a case where the current is applied to the bus bar 4 from an internal circuit of the Hall IC 1.

### Third Embodiment

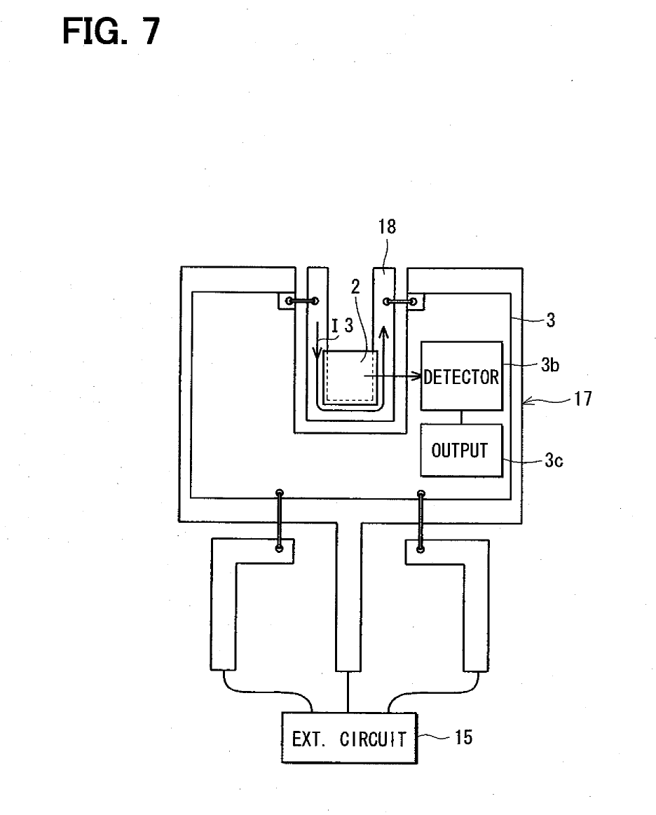

FIG. 7 shows a Hall IC 17 according to a third embodiment of the present disclosure. Difference between the third and second embodiments is that the IC 11 in FIG. 7 includes no conductive pattern for applying the test current through the lead frame.

The IC circuit portion 3 of the Hall IC 17 is coupled with the lead frame 18 as the conductive pattern through a bonding wire or the like. The lead frame 18 is independently disposed in a semiconductor package. The Hall element 2 is disposed around a current path of the current I3 flowing through the lead frame 18. The lead frame 18 has a rectangular shape such as a C shape along with a periphery of the Hall element 2.

The lead frame 18 has a thickness in a range between a few hundreds microns and a few millimeters, which is thicker than a conductive pattern formed from a semiconductor multi-layered structure. Accordingly, a large test current 13 can be applied to the lead frame 18, so that a large test magnetic field can be applied to the Hall element 2. Further, the lead frame 18 is disposed around the Hall element 2, so that the magnetic field intensity increases.

Since the hall IC 17 includes the lead frame 18, the large current can be applied to.

Further, a voltage is supplied to the IC circuit portion 3 from the external circuit 15, and the IC circuit portion 3 flows the test current I3 through the lead frame 18. The large test current I3 flows through the lead frame 18, so that the strong test magnetic field is applied to the Hall element 2. Thus, the magnetic field application test in a wide magnetic field range can be performed.

### Fourth Embodiment

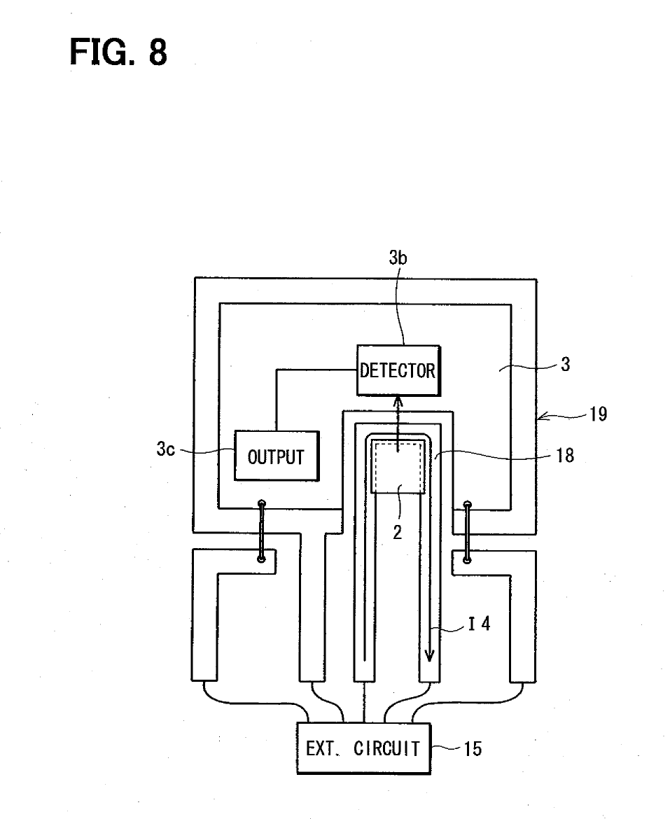

FIG. 8 shows a Hall IC 19 according to a fourth embodiment of the present disclosure. Difference between the fourth and third embodiments is such that a current is directly applied to the lead frame 18 from the external circuit 15. The external circuit 15 is capable of flowing a current I4 to the lead frame 18. The external circuit 15 can apply a large current to the lead frame 18. Accordingly, the strong test magnetic field can be applied to the Hall element 2. Thus, the magnetic field application test in a wide magnetic field range can be performed.

(Modifications)

Although the bus bar 4 having the rectangular shape provides the conductive pattern, the bus bar 4 may have a partially rounded U shape or a rounded C shape. Alternatively, the bus bar 4 may have a coil shape.

Alternatively, the Hall IC may have a capacitor therein. The capacitor accumulates electric charges so that the capacitor applies the test current.

Although the Hall IC 1 includes two Hall elements 2 as a magneto-electric conversion element, a magneto resistive effect (MRE) element, a magneto impedance (MI) element or the like may be used for the magneto-electric conversion element.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor integrated circuit for detecting a magnetic field comprising:
a magneto-electric conversion element for detecting the magnetic field and converting a detected magnetic field to an electric signal;
a conductive pattern for flowing a test current therethrough, the conductive pattern disposed around the magneto-electric conversion element;
a detection element for detecting the electric signal of the magneto-electric conversion element when the test current flows through the conductive pattern; and
an output element for outputting a test result based on the electric signal detected by the detection element.

2. The circuit according to claim 1, wherein
the test current is constant.

3. The circuit according to claim 1, further comprising:
a current application circuit for applying the test current to the conductive pattern.

4. The circuit according to claim 1, wherein
the test current is supplied from an external circuit.

5. The circuit according to claim 1, wherein
the conductive pattern is provided by a wiring layer in a multi-layered semiconductor chip.

6. The circuit according to claim 5, wherein
the wiring layer is made of one of a metallic layer and a poly crystalline silicon layer, a metallic layer, and a poly crystalline silicon layer

7. The circuit according to claim 5, wherein
the magneto-electric conversion element is provided by a thin plate layer in the multi-layered semiconductor chip, and
the conductive pattern is disposed on a side of the magneto-electric conversion element.

8. The circuit according to claim 7, wherein
the conductive pattern is disposed along with a periphery of the magneto-electric conversion element.

9. The circuit according to claim 1, wherein
the conductive pattern has a rectangular shape.

10. The circuit according to claim 9, wherein
the conductive pattern has a partially rounded U shape or a rounded C shape.

11. The circuit according to claim 9, wherein
the conductive pattern provides a coil.

12. The circuit according to claim 7, wherein
the magneto-electric conversion element and the conductive pattern are disposed on a same layer in the multi-layered semiconductor chip.

13. The circuit according to claim 7, wherein
the magneto-electric conversion element and the conductive pattern are disposed on different layers in the multi-layered semiconductor chip, respectively.

14. The circuit according to claim 1, wherein
the magneto-electric conversion element is a Hall element.

15. The circuit according to claim 14, wherein
the Hall element is made of one of silicon, InAs and GaAs.

16. The circuit according to claim 1, wherein
the magneto-electric conversion element is a magneto resistive effect element or a magneto impedance element.

17. The circuit according to claim 1, further comprising:
a lead frame as an inner wiring, wherein
the lead frame provides the conductive pattern.

18. The circuit according to claim 1, further comprising:
a capacitor to be energized from an external circuit, wherein
the capacitor flows the test current in the conductive pattern when the capacitor is charged.

19. A semiconductor integrated circuit for detecting a magnetic field comprising:
a Hall element for detecting the magnetic field and converting a detected magnetic field to an electric signal;
a bus bar for flowing a constant test current therethrough, the bus bar surrounding the Hall element; and
a circuit having a detection portion, an output portion and a current application circuit, wherein
the current application circuit applies the constant test current to the bus bar,
the detection portion detects the electric signal of the Hall element when the constant test current flows through the bus bar,
the bus bar has one of an angulated C shape, an rounded C shape, or a partially rounded U shape,
the detection portion determines that the Hall element is normal when a voltage change of the electric signal before and after application of the test current is equal to or smaller than a predetermined threshold value,
the detection portion determines that the Hall element is abnormal when the voltage change is larger than the predetermined threshold value, and
the output portion outputs a test result that the Hall element is normal or abnormal.
